(19) United States
(12) Patent Application Publication
(10) Pub. No.: US 2008/0092005 A1
(43) Pub. Date: Apr. 17, 2008

(54) Scan Testing Interface

(76) Inventors: William V. Huott, Holmes, NY (US); Norman K. James, Liberty Hill, TX (US); Bran C. Monwai, Austin, TX (US)

Correspondence Address: DILLON & YUDELL LLP, 8911 N. CAPITAL OF TEXAS HWY.,, SUITE 2110, AUSTIN, TX, 78759, US

(21) Appl. No.: 11/535,305

(22) Filed: Sep. 26, 2006

(51) Int. Cl. G01R 31/28; G06F 11/00

(52) U.S. Cl. 714/738

(57) ABSTRACT

A system, method, and computer program product for scan testing a device under test (DUT). In one embodiment, compressed test data comprising packets are received at a serial test data input. The packets contain encoded data characterizing a test data bit stream and each includes a bucket select field and a fill value field. The bucket select field contains an bucket select value that maps to a length of a bit-string. The fill value field contains a fill value indicating the uniform binary value of the bit-string. The compressed test data is then expanded and the expanded test data is scanned into internal structures of the DUT to test internal structures of the DUT. In a preferred embodiment, the compressed test data is received at a first clock rate. The test data is expanded and scanned into the internal structures of the DUT at a second clock rate that is higher than the first clock rate.

### BACKGROUND OF THE INVENTION

1. Technical Field

The present invention generally relates to test circuits utilizing serial test data input. In particular, the present invention relates to an apparatus, system and method for encoding and processing serial input test vectors for scan testing of integrated circuits.

2. Description of the Related Art

The development of increasingly complex integrated circuits (ICs) on smaller IC chip structures and circuit boards depends in part on the ability to adequately test the circuits to ensure proper operation. A critical area in hardware system development is therefore the production testing of ICs. Such testing is becoming increasingly difficult as the logic gate density of ICs increases and smaller geometries, copper interconnects, and low-K dielectrics promote new types of defects that require additional test pattern coverage. One method for testing ICs is known as boundary scan testing. Boundary scan testing was developed in accordance with the specification developed by the Joint Test Action Group (JTAG) which was standardized by the IEEE standard number 1149 “Standard Test Access Port and Boundary-Scan Architecture.” This standard defines a serial protocol for accessing and controlling the signal levels on the pins of a digital circuit to test circuit interconnects and has some extensions for testing the internal sub-block circuitry within the IC chip.

Testing increasingly complex and dense circuitry requires an increase in the number of test data inputs, sometimes referred to as “test patterns” or “test vectors,” so that all or a substantial portion of possible input states are covered by the testing procedure. ICs are often tested for correct operation at the fabrication facility using a specialized external test device such as an Automated Test Equipment (ATE) used in boundary scan testing applications. The wafer on which the object circuitry to be tested (referred to hereinafter alternatively as a device under test (DUT)) is fabricated may be test probed or the packaged part, typically a packaged IC chip or printed circuit board, may be tested. Serial test vectors are stored and/or generated by ATE and sequentially applied to multiple input ports (pads or pins) on the DUT. The output results are compared with specified target results. The actual attained fault coverage is generally less than 100% and depends on the number and quality of the input test vectors as well as the complexity of the tested circuitry.

For circuit testing in which input test vectors are input serially such as via boundary scan input ports, the test vector input scan time may be the most significant source of testing delay. A contributing factor to scan input delay is the substantial clock speed mismatch that generally exists between the DUT and the external ATE. For example, a given DUT may be designed to operate at 4 GHz, while the ATE hardware may scan in test vectors into the DUT using the IEEE 1149.1 (JTAG) protocol at 100 MHz.

Accordingly, there exists a need for improved test data scan input methods and systems that address the problems associated with the speed mismatch between ATE and a DUT and consequent delay in scan testing. The present invention addresses this and other needs unaddressed by the prior art.

### SUMMARY OF THE INVENTION

A system, method, and computer program product for scan testing a device under test (DUT) are disclosed herein. In one embodiment, compressed test data comprising packets are received at a serial test data input. The packets contain encoded data characterizing a test data bit stream and each includes a bucket select field and a fill value field. The bucket select field contains a bucket select value that maps to a length of a bit-string. The fill value field contains a fill value indicating the uniform binary value of the bit-string. The compressed test data is then expanded and the expanded test data is scanned into internal structures of the DUT to test internal structures of the DUT. In a preferred embodiment, the compressed test data is received at a first clock rate. The test data is expanded and scanned into the internal structures of the DUT at a second clock rate that is higher than the first clock rate.

The above as well as additional objects, features, and advantages of the present invention will become apparent in the following detailed written description.

### BRIEF DESCRIPTION OF THE DRAWINGS

The novel features believed characteristic of the invention are set forth in the appended claims. The invention itself however, as well as a preferred mode of use, further objects and advantages thereof, will best be understood by reference to the following detailed description of an illustrative embodiment when read in conjunction with the accompanying drawings, wherein:

FIG. 1 is a high-level block diagram depicting a test system employing a boundary scan architecture in accordance with the present invention;

FIG. 2 is a high-level block diagram illustrating a scan test path within the boundary scan architecture depicted in FIG. 1;

FIG. 3A depicts a bit value representation of a compression encoded packet in accordance with one embodiment of the present invention;

FIG. 3B illustrates a string of compression encoded packets in accordance with the present invention;

FIG. 3C depicts a tabular representation of the mapping between bucket select values and bit-string length values in accordance with one embodiment of the present invention;

FIG. 4 is a high-level flow diagram illustrating steps performed during compression encoding of test input data and scan-in processing of the compressed test data in accordance with the present invention; and

FIG. 5 is a high-level flow diagram depicting steps performed during expansion of packetized test vector data in accordance with the present invention.

### DETAILED DESCRIPTION OF ILLUSTRATIVE EMBODIMENT(S)

The present invention is generally directed to testing of integrated circuits (ICs). The present invention is further directed to a system, method and computer program product that provide an on-chip and/or off-chip mechanism for scan testing an IC, generally referred to herein as a device under test (DUT). In one aspect, the present invention may be deployed as part of a compression encoding module for compressing serial test data input utilized for boundary scan testing. In another aspect, the present invention comprises decompression/decoding logic for restoring the compressed input test vector data which can then be scanned into the DUT at the DUT clock speed. As explained in further detail below, the present invention may encompass a boundary scan architecture having a data and clock interface into which input test vectors are scan loaded and processed during scan testing of a DUT. The boundary scan architecture of the present invention employs an efficient compression technique that provides flexible and lossless compression and decompression of the input test vectors.

The present invention covers compression encoding techniques to reduce test data volume and test pattern delivery time for a serial scan-in test application. Fundamentally, the compression encoding entails packetizing a serial input bit-string, comprising one or more test vectors, into multiple packets each including at least two basic fields. One field, referred to in a preferred embodiment as a “bucket select field,” directly or indirectly encodes the bit length of a bit-string encoded by the packet. The other field is a fill value field that indicates the uniform binary value (either 1 or 0) of the string. This combination of a bucket select field and fill value field is particularly efficient when applied to boundary scan test vector input data which is characterized as including relatively long strings of uninterrupted 1's or 0's.

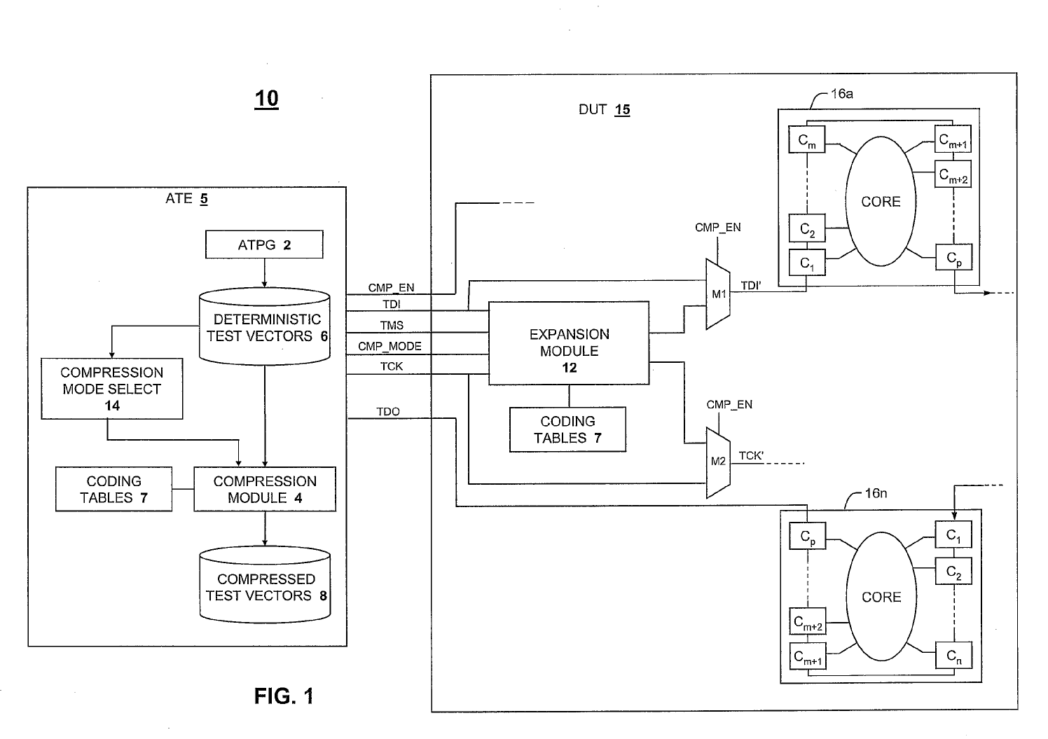

With reference now to the figures, wherein like reference numerals refer to like and corresponding parts throughout, and in particular with reference to FIG. 1, there is depicted a high-level block diagram illustrating a test system 10 in accordance with the present invention. Test system 10 employs boundary scan test facilities provided by an automated test equipment (ATE) 5 and a device under test (DUT) 15 having a compatible boundary scan architecture. Boundary scan is a well-known method often utilized for testing interconnects on printed circuit boards or sub-blocks as well as internal logic within an IC. A specification for boundary scan testing was developed by the Joint Test Action Group (JTAG) and was standardized as the IEEE Std. 1149.1-1990 which is incorporated herein by reference in its entirety.

The boundary scan functionality provided by ATE 5 and the boundary scan architecture of DUT 15 provides a means to test interconnects and clusters of logic, memories, etc., generally depicted in FIG. 1 as multiple processor cores 16a-16n, within DUT 15 while minimizing test probe contact requirements. ATE 5 generally comprises data processing and storage facilities for storing test data and controlling ICs under test via a restricted number of primary inputs for clock and data input. An automatic test-pattern generator (ATPG) 2 generates test vector patterns 6 stored in suitable storage media within ATE 5. During boundary scan testing, test vectors 6 are applied as test data inputs into DUT 15. ATE 5 further includes a compression module 4 for compressing test vectors 6 generated by ATPG 2. The compression of test vectors 6 reduces both boundary scan test time and test data volume as explained in further detail below.

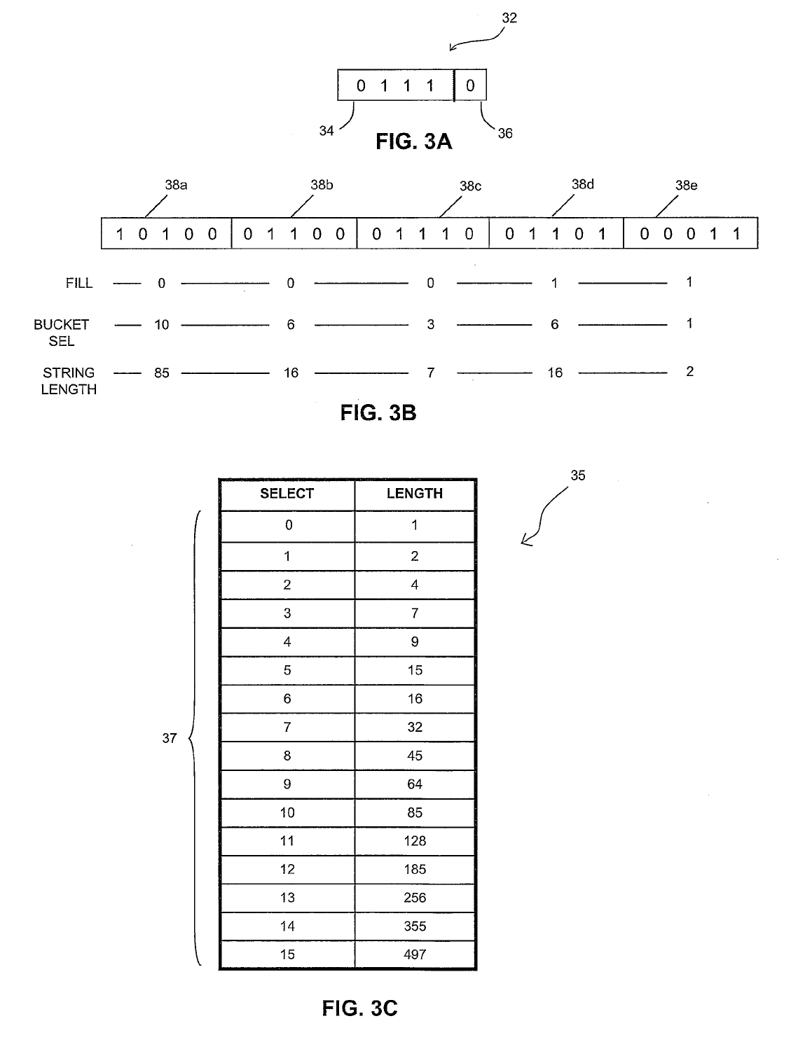

ATE 5 further includes electronic storage for storing compressed test vectors 8 resulting from the compression of test vectors 6 by compression module 4. As explained in further detail below with reference to FIGS. 3A-3C, compressed test vectors 8 are generated using a lossless compression technique in which uniform value bit-strings (i.e., uninterrupted strings of 1's or 0's) are packet encoded. The packets comprise fields including a bucket select field (depicted and explained with reference to FIGS. 3A-3C) that encodes the length of the bit-string encoded by the packet. Each packet further includes a fill value field containing either a logic 1 or logic 0 to indicate the uniform binary value of the corresponding bit-string.

The packet encoding performed by compression module 4 is defined, in part, in terms of packet field characteristics such as the bit-length of particular fields and overall packet size. The embodiment depicted in FIG. 1 further includes a compression mode select module 14 communicatively coupled to compression module 4 for selecting the compression mode and/or switching between compression modes used by compression module 4 in accordance with the data pattern characteristics of the test vectors 6. As explained in further detail below, in addition to dictating the required expansion/decoding procedure (discussed below), the selected compression mode may substantially affect compression resolution and the efficiency of the overall scan testing process. Compression mode select module 14 may be utilized to selectively modify the manner of compression in terms of packet and packet field sizes as well as bucket select field mapping such as that depicted and explained below with reference to FIG. 3C. Compression mode select module 14 may be integrally incorporated within compression module 4 and may set the compression mode in accordance with user selection, such as for selecting a desired, user specified test configuration, as well as dynamically determining the compression mode in accordance with bit-string characteristics such as binary value continuity of the test vector bit strings.

In support of its compression encoding function, compression module 4 accesses data contained in a set of coding tables 7. As depicted and explained in further detail below with reference to FIG. 3C, the data within coding tables 7 includes a tabular mapping between the bucket select values contained in the bucket select fields of the encoded packets and corresponding bit-string lengths. Compression module 4 selects and utilizes one or more of coding tables 7 as determined by the compression mode selected and set by compression model select module 14.

ATE 5 includes a boundary scan interface with DUT 15. In accordance with the IEEE 1149 standard the boundary scan interface includes a test data input, TDI, a test mode select input, TMS, a test clock input, TCK, and a test data output, TDO. In accordance with the invention, the interface further includes a compression enable input, CMP_EN, and a compression mode select input, CMP_MODE. The boundary scan interface is preferably a multi-pin interface added to the chip on which DUT 15 is fabricated and designed so that multiple chips on a circuit board (not depicted) can be daisy chained together using the boundary scan lines. In this manner, a test probe need only be connected to a single boundary scan port to have access to all chips on a circuit board.

Test data input and output lines TDI and TDO are serial. An ATE clock input is applied by ATE 5 at the TCK input. One bit of data is transferred in and out per TCK clock pulse at the TDI and TDO pins, respectively. The frequency of TCK varies depending on the chip under test and the ATE. In the present state of the art, TCK runs on the order of 10-200 MHz.

During boundary scan testing using test system 10, the packetized, compressed test vectors 8 are serially delivered over the TDI input from ATE 5 to DUT 15 where the compressed test vector data is expanded, scanned in, and applied to the interconnects and internal logic of cores 16a-16n. To accommodate the serially scanned in data, the boundary scan architecture of DUT 15 includes a boundary scan register comprising multiple scan latch cells C₁-Cₚ connected between each pin (not depicted) of each of the cores 16a-16n and the internal core logic. The boundary scan register comprising the multiple scan latch cells C₁-Cₚ coupled in association with cores 16a-16n provides a serial scan path that intercepts the signals between the core logic within cores 16a-16n and the boundary scan interface pins. In this manner, the boundary scan register provides a mechanism for controlling the logic blocks within cores 16a-16n in the same manner as if each of the logic blocks was a physically independent circuit.

Scan latch cells C₁-Cₚ can be programmed via scan chain logic (not depicted) in a variety of testing modes. For example, one of cells C₁-Cₚ may be programmed to drive a signal onto a pin and across an individual trace on the board. The cell at the destination of the board trace can then be programmed to read the value at the pin, verifying the board trace properly connects the two pins. If the trace is shorted to another signal or if the trace has been opened, the correct signal value will not reach the destination pin, and DUT 15 will be identified as faulty.

During regular (i.e. non-test) operation, latch cells C₁-Cₚ for cores 16a-16n are set so that they have no effect on the circuit, and are therefore operationally invisible in non-test operating mode. However, when DUT 15 is configured in a scan test mode, latch cells C₁-Cₚ enable a data stream to be passed from one latch cell to the next. Once a complete test input vector has been passed into a given one or more of cores 16a-16n under test, it can be latched into place within latch cells C₁-Cₚ. In this manner, latch cells C₁-Cₚ set up test conditions for cores 16a-16n by enabling specified data vector placement within DUT 15. The relevant output logic states as revealed in the receiver cells among cells C₁-Cₚ can then be fed back into the ATE 5 portion of test system 10 by shifting the latched data through the scan path and finally back through the TDO port to ATE 5 so that it can be analyzed. In the foregoing manner, boundary scan test systems such as that depicted in FIG. 1 can efficiently and comprehensively access and test various interconnects and logic on DUT 15.

To expand the compressed test vectors 8 for scan in test application, DUT 15 includes an expansion module 12 that decodes the packetized compressed data. Expansion module 12 is communicatively coupled to ATE 5 via the TDI, CMP_MODE, and TCK ports of the boundary scan interface. Expansion module 12 preferably includes combinatorial and sequential logic modules that expand the compressed test vector data by decoding a stream of packets in which the test vector data has been encoded. Expansion module 12 receives the packetized compressed test vector data received from the TDI input. The CMP_MODE input from ATE 5 sets the expansion mode for expansion module 12 consistent with the currently set compression mode set by compression mode select module 14. In one embodiment, the selected expansion mode determines which bucket select conversion table among multiple such tables expansion module 12 utilizes to decode/expand the packets. In the depicted embodiment, such alternatively selectable tables are stored and accessed from coding tables 7, which may be accessed from within or external to DUT 15. Expansion module 12 decodes the packets in accordance with the selected expansion mode such that the original test vector data is restored from the compressed vector data and may then be applied as scan data patterns for the scan chains comprising latch cells C₁-Cₚ.

Test system 10 is designed to accommodate either compression or non-compression based boundary scan testing procedures. Depending on whether ATE 5 has been programmably or otherwise set to operate in compression mode, ATE 5 delivers either the compressed test vector data from compressed test vectors 8 or the uncompressed test vectors 6 to DUT 15 via the TDI port.

When operating in non-compression boundary scan test mode, ATE 5 delivers the test vector data from uncompressed test vectors 6 to the TDI port where it is selected by a multiplexer M1, in accordance with control signal CMP_EN, to be scanned into the boundary scan registers within DUT 15. Operating in non-compression scan testing mode further results in a second multiplexer M2 selecting, in accordance with the control signal CMP_EN, the ATE clock signal TCK from the boundary scan interface to be applied to the boundary scan registers comprising scan latch cells C₁-Cₚ.

When operating in compression boundary scan test mode, ATE 5 delivers the compressed test vectors 8 in the form of encoded packets to the TDI port where they are received and processed by expansion module 12. Multiplexer M1 selects, in accordance with the CMP_EN control signal, the expanded bit-string output from expansion module 12 to be scanned in to the boundary scan registers within DUT 15. Operating in compression mode further results in a second multiplexer M2 selecting, in accordance with the CMP_EN control signal, a DUT clock signal from expansion module 12 or elsewhere within DUT 15, to be applied to the boundary scan registers comprising scan latch cells C₁-Cₚ.

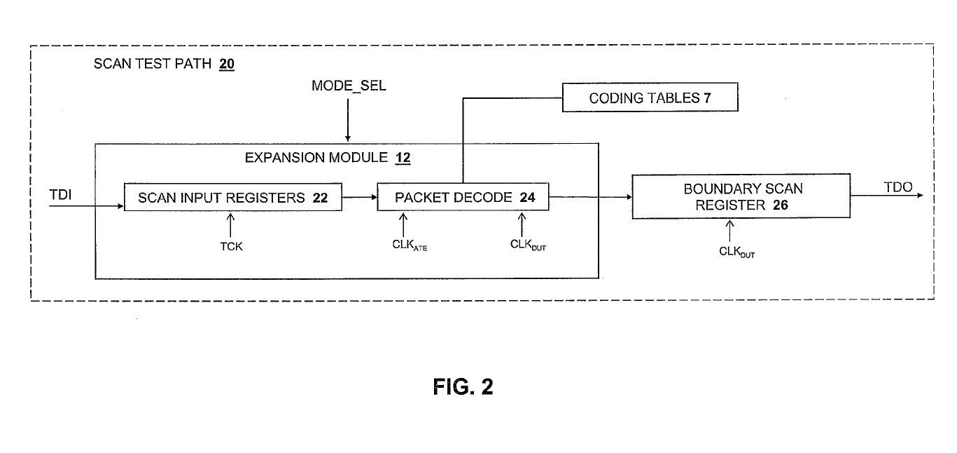

Referring to FIG. 2, there is depicted a high-level block diagram illustrating a compression mode scan test path within the boundary scan architecture depicted in FIG. 1. Some of the features, such as multiplexers, that are not necessary for an understanding of the function of the scan test path as it operates during compression mode scan-in, are omitted from FIG. 2. Specifically, FIG. 2 depicts a scan test path 20 that generally comprises expansion module 12 communicatively coupled a boundary scan register 26 that collectively represents the serial scan path provided by scan latch cells C₁-Cₚ. Also coupled to expansion module 12 is a set of coding tables 7 to be used by expansion module 12 for decoding/expanding the packet encoded input. Expansion module 12 receives compressed test vector data from the TDI port and also receives the expansion mode select signal from the CMP_MODE port. Expansion module 12 further includes one or more scan input registers 22 that receive and temporarily store the compressed, packetized test vector input from TDI. The output from scan registers 22 is received as input by a packet decode module 24.

Scan test path 20 is designed to receive and process test vector data from ATE 5 “at speed” rather than in an intermittent or otherwise unsynchronized manner. Conventionally, and when operating in a non-compression mode using the non-compression mode path depicted in FIG. 1, the test vector data from TDI is scanned into the boundary scan registers within DUT 15 at the ATE clock rate to permit synchronized operation between the ATE and DUT boundary scan devices. For compression mode, the present invention provides for faster scan-in processing by transferring the lower volume packetized test vector data into the DUT scan input registers 22 at the typically lower ATE clock speed and subsequently scanning in the test vector data using a higher speed clock signal native to DUT 15 or otherwise available on the DUT side of the scan test process.

In compression mode, the compressed, packetized test vectors are serially cycled into scan input registers 22 at the ATE clock rate TCK. Once registered within the scan input registers 22, the packets are serially transferred to decode module 24, again at the ATE clock rate. Packet decode module 24 performs the test vector expansion function by decoding each of the packets received from scan input registers 22. The decoding results in the expansion that restores the original test vector data 6 from the packetized, compressed test vectors 8.

Decode module 24 decodes received packets in accordance with a coding table included within coding tables 7. With reference now to FIGS. 3A-3B in conjunction with FIG. 2, the manner in which decode module 24 decodes/expands the input packets using tabular packet coding data is now described. Referring first to FIG. 3A, there is depicted a bit value representation of a five-bit, compression-encoded packet 32 such as may be serially delivered from ATE 5 to decode module 24. Packet 32 comprises a four-bit bucket select field 34 and a one-bit fill value field 36. In accordance with the present invention, bucket select field 34 contains a four-bit binary bucket select value, 0111, that maps to a bit-string length value specified by a corresponding coding table. The bit-string length value is the length of the uniform value bit-string, such as an uninterrupted string of twelve logic ones or zeros within a test vector input string, which was compressed into packet 32. Fill value field 36 contains a fill value, 0, which indicates the uniform binary value of the corresponding bit-string is a logic low or zero.

FIG. 3B illustrates a string of packets 38a-38e encoded in accordance with the present invention and having the same bit field structure as packet 32. Each of packets 38a-38e comprises a one-bit fill value field (the rightmost bit of each packet in the figure) that determines the logic value of the corresponding compressed string. Each packet further includes a four-bit bucket select field containing a bucket select value. FIG. 3B together with FIG. 3C depict the bucket select values (converted to decimal values for ease of illustrative reference) associated with corresponding bit-string lengths to which the bucket select values map. FIG. 3C depicts a coding table 35 that may be included within coding tables 7 and accessed by decode module 24 for decoding/expanding the received packets such as packets 38a-38e. In accordance with the invention, coding table 35 contains 16 records 37 each associating its respective one of the 16 bucket select values 0-15 (binary 0000 through 1111) with a respective bit-string length value (1, 2, 4, 7, . . . , 256, 355, 497).

For packets having an n-bit bucket select field, a coding table may have up to 2ⁿ different bucket select values. In accordance with the present invention, the tabular mapping provided by a coding table such as coding table 35 is preferably selected so that for each of the 2ⁿ bucket select values, in which each of the 2ⁿ bucket select values maps to one of a set of 2ⁿ different bit-string length values, one or more of the bit-string length values is specified to be greater than 2ⁿ. For example, and referring to FIG. 3B in conjunction with FIG. 3C, the bucket select value for packet 38a is a decimal ten (binary 1010) that associatively maps via coding table 35 to a decimal 85. To directly encode an 85 bit bit-string length would require a seven bit field (binary 1010101). In this manner, the tabular coding depicted in FIGS. 3B and 3C enables decode module 24 to determine bit-string lengths greater than 2ⁿ by using an n-bit bucket select field as a pointer that indexes coding table 35. Coding table 35 or a compression table having the same bucket select to bit-string length coding is utilized by processing means within ATE 5 or otherwise to compress the test vector data 6 into the packetized, compressed test data 8 received by decode module 24.

As depicted in FIG. 3C, the property of the bucket select to bit-string length mapping of coding table 35 as having bit-string lengths greater than 2⁴=16 for a four-bit bucket select field, results in discontinuities or “gaps” between the bit-string values of sequentially contiguous table records. For example, for the sequentially contiguous records containing bucket select values of 11 and 12, the corresponding bit-string length values are 128 and 185, respectively. An additional criterion for the bucket select to bit-string length indexing utilized for encoding/compressing and decoding/expanding packets relates to encoding/decoding a uniform value bit-string having a length that falls within such gaps. Namely, the bit-string length values associated with bucket select values within coding tables such as coding table 35 are selected so that no two different pairs of bit-string length values (e.g. 2 and 7, and 1 and 9, or 2 and 7, and 2 and 9) have an equal combined bit-string length value. In this manner, the number of secondary “gaps” (i.e. bit-strings having gaps requiring a third or more packets to encode) are minimized.

Decode processing performed by packet decode module 24 using one or more of coding tables 7 such as coding table 35 runs synchronously with the ATE clock rate, TCK, in terms of clock cycles per bit serially transferred. The expansion of packets results in substantially greater test vector data volume, requiring that the decoded data be output from packet decode module 24 at a substantially higher clock rate, in terms of cycles per bit transferred, than the ATE clock rate, TCK. To this end, a DUT clock input, CLK_{DUT}, having a higher clock rate that TCK is applied to the output processing stages of packet decode module 24. In this manner, the expanded test vector data can be cycled from packet decode module 24 “at speed” relative to the compressed test vector data being cycled into scan input registers 22 and the input processing stages of packet decode module 24. The DUT clock input, CLK_{DUT}, is preferably a clock signal native to DUT 15 or otherwise available on the DUT side of the scan test process. In the present state of the art, CLK_{DUT} may typically range from 1 to 5 GHz.

The expanded test vector data is cycled from packet decode module 24 into the scanning stages comprising boundary scan register 26 where it is processed in accordance with boundary scan testing procedures. On the output side of boundary scan register 26, the output scan data is serially cycled from the output side latch cells within processor cores 16a-16n to a test data output port, TDO, on the boundary scan interface through which the output data is received by ATE 5. Since the TDO port may share the same operational frequency limitations as TDI, test vectors may be scanned in with compressed mode active, while the corresponding scan-out results are scanned out via TDO in non-compressed mode.

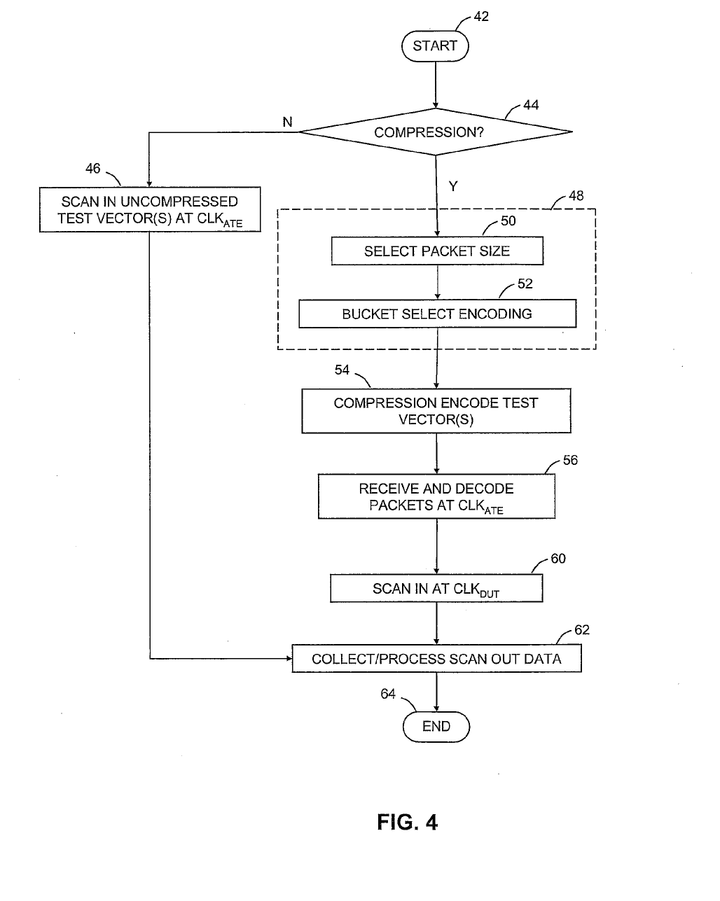

Referring to FIG. 4, there is depicted a high-level flow diagram illustrating steps performed during packet-encoded compression of test input data and scan-in processing of the compressed test data such as may be performed by the boundary scan architecture of ATE 5 and DUT 15 in accordance with the present invention. The process begins as illustrated at steps 42 and 44 with a determination by ATE 5 of whether boundary scan testing will be performed using compression or non-compression mode. When ATE 5 is programmably or manually set to operate in non-compression mode the logic level of the CMP_EN control signal is set accordingly and the uncompressed test data vectors 6 are scanned into DUT 15 via the TDI port (step 46) and processed and scanned back out to ATE 5 via TDO using boundary scan processing convention (step 62).

If, as shown at steps 48, 50, and 52, the system is operating in compression mode as reflected by CMP_EN, compression mode select module 14 selects a particular compression mode that specifies a packet size and bucket select encoding to be utilized for encoding (and subsequently decoding) the packets. In one embodiment, compression mode select module 14 selects a compression mode in accordance with binary value continuity properties of the strings within test vectors 6. For the embodiments depicted in FIGS. 1 and 2, compression mode select module 14 effectively sets the scan-in mode by selecting one or more of coding tables 7 having the desired packet size and bucket select encoding.

The process continues with one or more of test vectors 6 being compressed using the one or more of coding tables 7 corresponding to the selected compression mode (step 54). The compression encoding of the serial test vector strings into packets preferably accounts for uniform value strings that fall within bit-string length value gaps between sequentially contiguous coding table records or that otherwise require more than one packet to compress a given string of uninterrupted 1-bits or 0-bits. To this end, the compression depicted at step 54 includes compression module 4 selecting as the bucket select values for the multiple packets, the combination of two or more bucket select field values that will minimize the total number of packets required to encode the uniform value bit string in accordance with the associated bit-string length values. Next, as illustrated at step 56, the resultant packets are received and decoded by DUT 15 at the ATE clock rate, TCK. The expanded serial test vector data is then cycled from packet decode module 24 into boundary scan register 26 at the higher frequency DUT clock, CLK_{DUT} (step 60). The scanned test vector output data is cycled from boundary scan register 26 and into ATE 5 for processing via the TDO port and the process ends as shown at steps 62 and 64.

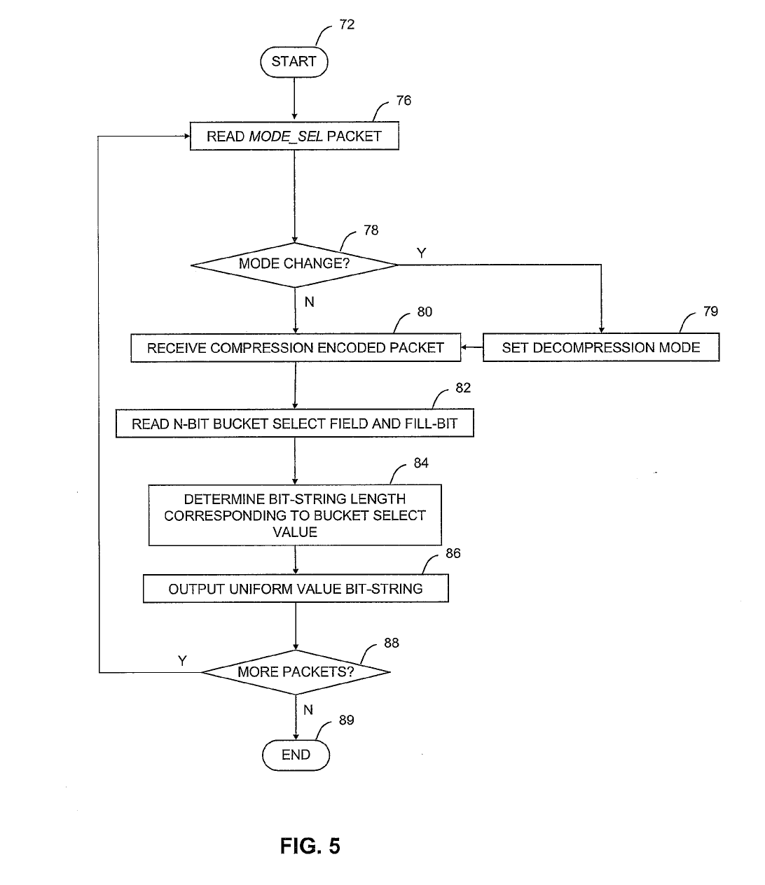

With reference to FIG. 5, there is illustrated a high-level flow diagram depicting steps performed during expansion of compressed, packetized test vector data such as may be performed by test system 10 in accordance with the present invention. As explained above with reference to steps 48, 50, and 52, compression mode select module 14 sets the compression mode in accordance with data string continuity properties of test vectors 6. The selected compression mode will necessarily determine the expansion mode (i.e. the one or more of coding tables to be utilized for decoding the packets).

The embodiment depicted in FIG. 5 preferably addresses boundary scan testing situations in which compression mode select module 14 may switch scan-in modes at some point during a given scan-in procedure. Such switching may occur as dynamically set by compression mode select module 14 in accordance with shifts data continuity properties of the input test vectors 6. To address such scan-in mode switching, a dedicated mode select packet (not depicted) may be included in the stream scanned into expansion module 12. As illustrated at steps 72, 76, and 78 the packet expansion processing begins with expansion module 12 reading the mode select packet to determine whether or not the scan-in mode has changed. If so, packet decode module 24 switches to one or more of tables 7 corresponding to the new scan-in mode (step 79).

Whether or not the compression/expansion mode has changed, the process continues as shown at step 80 with packet decode module 24 reading the bucket select and fill value fields of the packets compressed in accordance with the specified compression mode. Packet decode module 24 directly determines the logic value (1 or 0) of each compressed bit-string encoded within each packet in accordance with the fill value contained within the fill value field of each packet (step 82). The bit-string length for each packet is determined by matching or otherwise correlating the n-bit bucket select value within each packet with the 2ⁿ bucket select values in the selected one or more of coding tables 7 to find the record containing the correct bit-string length (step 84). Packet decode module 24 generates a uniform value bit-string having the fill value and bit-string length values determined at steps 82 and 84 and the packet expansion processing continues for the remaining packets as depicted as steps 86, 88 and 89.

The system and method disclosed herein provide a simple and efficient compression scheme that may be implemented on the DUT and ATE to minimize the scan-in delivery time. In addition to providing lossless ATE-side compression and DUT-side expansion, the invention's packetized compression/expansion coding scheme is computationally inexpensive thus requiring minimal additional logic be added to conventional DUT-side boundary scan architecture.

The foregoing embodiments depicted the invention as deployed using circuit and logic modules deployed on a device under test and automated test equipment used for boundary scan testing. The present invention is not limited to the specific embodiments depicted herein and may be practiced in alternative computer-implemented configurations. The invention may be embodied using any combination of hardware, firmware, and software and as such, embodiments may be embodied in the form of computer program code containing instructions embodied in tangible media, such as floppy diskettes, CD-ROMs, hard drives, or any other computer-readable storage medium, wherein, when the computer program code is loaded into and executed by a computer, the computer becomes an apparatus for practicing the invention.

While the invention has been particularly shown and described with reference to a preferred embodiment, it will be understood by those skilled in the art that various changes in form and detail may be made therein without departing from the spirit and scope of the invention.

What is claimed is:

1. A method for scan testing a device under test (DUT) comprising:
receiving, at a serial test data input, compressed test data comprising packets of encoded data characterizing a test data bit stream, wherein the packets include a bucket select value that maps to a length of a bit-string, and a fill value indicating a uniform binary value of the bit-string;
expanding the compressed test data; and
testing the DUT using the expanded test data.

2. The method of claim 1, wherein the compressed test data is received by a test data input register from test equipment at a first clock rate, said testing the DUT using the expanded test data comprising scanning the expanded test data into a boundary scan register within the DUT at a second clock rate that is materially higher than the first clock rate.

3. The method of claim 1, said expanding comprising determining the bit-string length corresponding to the bucket select value within each packet, wherein the bucket select value for each packet is a member of a set of 2ⁿ pre-specified bucket select values, wherein n represents the bit length of the bucket select value and each of the 2ⁿ bucket select values maps to one of a set of 2ⁿ bit-string length values, wherein at least one of said set of 2ⁿ bit-string length values is greater that 2ⁿ.

4. The method of claim 3, wherein said bit-string length values are specified such that no two different pairs of bit-string length values have an equal combined bit-string length value.

5. The method of claim 1, said expanding the compressed test data comprising selecting between a first expansion mode that utilizes a first bucket select value bit length and a second expansion mode that utilizes a second bucket select value bit length.

6. The method of claim 1, further comprising compressing serial test data by reading the test data, and responsive thereto, generating packets, each packet including:
a bucket select value associated with a length of a bit-string; and
a fill value indicating the uniform binary value of the bit-string.

7. The method of claim 6, said compressing further comprising, for a given uniform value bit-string to be encoded into multiple packets, selecting a combination of two or more bucket select values each to be assigned to one of the multiple packets, the combination of two or more bucket select values selected in accordance with the corresponding associated bit-string lengths to minimize the number of packets required to encode the uniform value bit-string.

8. A system for scan testing a device under test (DUT) comprising:
a DUT serial test data input that receives compressed test data comprising packets of encoded data characterizing a test data bit stream, wherein the packets include a bucket select value that maps to a length of a bit-string, and a fill value indicating a uniform binary value of the bit-string;
an expansion module that expands the compressed test data; and
a test structure that tests the DUT using the expanded test data.

9. The system of claim 8, wherein the compressed test data is received by a test data input register from test equipment at a first clock rate, said test structure comprising a scan test structure that scans the expanded test data into a boundary scan register within the DUT at a second clock rate that is materially higher than the first clock rate.

10. The system of claim 8, said expansion module comprising modules that determine the bit-string length corresponding to the bucket select value within each packet, wherein the bucket select value for each packet is a member of a set of 2ⁿ pre-specified bucket select values, wherein n represents the bit length of the bucket select value and each of the 2ⁿ bucket select values maps to one of a set of 2ⁿ bit-string length values, wherein at least one of said set of 2ⁿ bit-string length values is greater that 2ⁿ.

11. The system of claim 10, wherein said bit-string length values are specified such that no two different pairs of bit-string length values have an equal combined bit-string length value.

12. The system of claim 8, said expanding the compressed test data comprising selecting between a first expansion mode that utilizes a first bucket select value bit length and a second expansion mode that utilizes a second bucket select value bit length.

13. The system of claim 8, further comprising a compression module for compressing serial test data by reading the test data, and responsive thereto, generating packets, each packet including:
a bucket select value associated with a length of a bit-string; and
a fill value indicating the uniform binary value of the bit-string.

14. The system of claim 13, said compression module further comprising, for a given uniform value bit-string to be encoded into multiple packets, means for selecting a combination of two or more bucket select values each to be assigned to one of the multiple packets, the combination of two or more bucket select values selected in accordance with the corresponding associated bit-string lengths to minimize the number of packets required to encode the uniform value bit-string.

15. A tangible computer-readable medium having encoded thereon computer-executable instructions for scan testing a device under test (DUT), said computer-executable instructions adapted to perform a method comprising:
receiving, at a serial test data input, compressed test data comprising packets of encoded data characterizing a test data bit stream, wherein the packets include a bucket select value that maps to a length of a bit-string, and a fill value indicating a uniform binary value of the bit-string;
expanding the compressed test data; and
testing the DUT using the expanded test data.

16. The computer-readable medium of claim 15, wherein the compressed test data is received by a test data input register from test equipment at a first clock rate, said testing the DUT using the expanded test data comprising scanning the expanded test data into a boundary scan register within the DUT at a second clock rate that is materially higher than the first clock rate.

17. The computer-readable medium of claim 15, said expanding comprising determining the bit-string length corresponding to the bucket select value within each packet, wherein the bucket select value for each packet is a member of a set of 2ⁿ pre-specified bucket select values, wherein n represents the bit length of the bucket select value and each of the 2ⁿ bucket select values maps to one of a set of 2ⁿ bit-string length values, wherein at least one of said set of 2ⁿ bit-string length values is greater that 2ⁿ.

18. The computer-readable medium of claim 17, wherein said bit-string length values are specified such that no two different pairs of bit-string length values have an equal combined bit-string length value.

19. The computer-readable medium of claim 15, said method further comprising compressing serial test data by reading the test data, and responsive thereto, generating packets, each packet including:
a bucket select value associated with a length of a bit-string; and
a fill value indicating the uniform binary value of the bit-string.

20. The computer-readable medium of claim 19, said compressing further comprising, for a given uniform value bit-string to be encoded into multiple packets, selecting a combination of two or more bucket select values each to be assigned to one of the multiple packets, the combination of two or more bucket select values selected in accordance with the corresponding associated bit-string lengths to minimize the number of packets required to encode the uniform value bit-string.
